(19) United States
(12) Patent Application Publication
(10) Pub. No.: US 2007/0137568 A1
(43) Pub. Date: Jun. 21, 2007

(54) RECIPROCATING APERTURE MASK SYSTEM AND METHOD

(76) Inventor: Brian E. SCHREIBER, Oakdale, MN (US)

Correspondence Address: 3M INNOVATIVE PROPERTIES COMPANY, PO BOX 33427, ST. PAUL, MN, 55133-3427, US

(21) Appl. No.: 11/275,170

(22) Filed: Dec. 16, 2005

(51) Int. Cl. C23C 16/00

(52) U.S. Cl. 118/718; 118/720; 118/726

(57) ABSTRACT

An apparatus for depositing a pattern of material on a substrate includes reciprocating aperture mask. A feed magazine houses a plurality of jigs, each of the jigs configured to support a mask having apertures defining a pattern. A shuttle mechanism receives a selected jig presented by the feed magazine and establishes contact between the mask of the selected jig and the substrate. The shuttle mechanism moves the selected jig in line with the substrate and relative to the deposition source so that deposition material passes through the apertures of the mask of the selected jig to develop the pattern of the deposition material on the substrate.

### TECHNICAL FIELD

The present invention is related to the use of aperture masks to deposit a pattern of material on a substrate.

### BACKGROUND

Patterns of material may be formed on a substrate through the use of an aperture mask or stencil. The aperture mask is positioned between the substrate and a deposition source. Material from the deposition source is directed toward the substrate and passes through apertures of the mask, forming a pattern on the substrate that corresponds to the pattern of the apertures.

Such patterns may be deposited on a substrate for various purposes. As one example, circuitry may be formed on the substrate by sequentially depositing materials through mask patterns to form circuit layers. Aperture masks may be used to form a wide variety of circuits, including discrete and integrated circuits, liquid crystal displays, organic light emitting diode displays, among others. Formation of small geometry circuit elements involves accurate alignment and position control of the substrate and the aperture mask. The present invention fulfills these and other needs, and offers other advantages over the prior art.

### SUMMARY

Embodiments of the present invention are directed to systems and methods for deposition of material on a substrate using a reciprocating aperture mask. One embodiment involves an apparatus for depositing a pattern of material on a substrate. The apparatus includes a delivery roller mechanism from which the substrate is delivered and a receiving roller mechanism upon which the substrate is received. A deposition source is positioned to direct deposition material toward the substrate. A feed magazine houses a plurality of jigs, each of the jigs configured to support a mask having apertures defining a pattern. A shuttle mechanism receives a selected jig presented by the feed magazine and establishes contact between the mask of the selected jig and the substrate. The shuttle mechanism moves the selected jig in line with the substrate and relative to the deposition source so that deposition material passes through the apertures of the mask of the selected jig to develop the pattern of the deposition material on the substrate.

The apparatus may further include one or more alignment arrangements. An alignment arrangement may be used to align the substrate relative to the mask, to align the mask relative to the substrate, and/or to adjust a position of the mask relative to the selected jig.

In one example, the mask includes fiducials and the jig includes datums. The mask alignment arrangement is configured to align the mask fiducials with the jig datums with respect to one or more axes. The mask alignment mechanism may include one or more controllable drivers coupled to the mask. The drivers controllably adjust the tension of the mask of the selected jig.

In another example, the apparatus includes a substrate alignment arrangement configured to adjust a position of the substrate and a mask alignment arrangement configured to adjust a position of the mask of the selected jig. The respective alignment arrangements are controllably adjustable to facilitate alignment between the substrate and the mask.

The substrate alignment mechanism may include markings on the substrate and a web guide that adjusts a transverse position of the substrate to a pre-defined position. The shuttle mechanism is configured to adjust a position of the mask of the selected jig so that a patterned portion of the substrate comes into alignment with the mask when the shuttle mechanism moves the selected jig in line with the substrate. According to one implementation, the substrate alignment mechanism includes a web location platform arrangement configured to adjust a location of the substrate relative to the mask as the shuttle mechanism moves the selected jig in line with the substrate.

In one configuration, the web location platform arrangement may include a support plate and a gas delivery arrangement. The gas delivery arrangement may be used to supply a volume of gas between the substrate and the support plate. In another configuration, the web location platform arrangement includes at least one roller disposed adjacent each respective end of the support plate. One or both of the rollers may be configured to cool the substrate as the substrate moves past the rollers. The gas delivery arrangement may supply a volume of gas between the substrate and the rollers to cool the substrate. In addition, an oscillator may be coupled to the support plate and configured produce oscillating motion of the support plate.

The substrate has a surface which is substantially planar. The shuttle mechanism is configured to move the selected jig relative to the substrate in a direction off-plane with respect to the plane of the substrate to engage and disengage the substrate from the mask of the selected jig. The shuttle mechanism is configured to move the selected jig in a first off-plane direction so that the mask engages the substrate prior to deposition, and to move the selected jig in a second off-plane direction so that the mask disengages with the substrate after completion of the deposition. The shuttle mechanism is configured to move the selected jig in a reciprocating manner for repeated use of the selected jig during deposition.

The apparatus may further include an outfeed mechanism and an outfeed magazine configured to house a plurality of used jigs. The outfeed mechanism moves the used jigs from the shuttle mechanism to the outfeed magazine. In some configurations, the feed magazine serves as the outfeed magazine. A feed mechanism of the feed magazine is configured to receive used jigs presented by the shuttle mechanism.

In some implementations, the masks of at least some of the plurality of jigs define patterns differing from the masks of others of the plurality of jigs. The substrate may be a continuous web. The masks and/or the substrate may comprise a polymeric film.

Another embodiment of the invention is directed to a method of depositing a pattern of material on a substrate. A selected jig of a plurality of jigs is moved from a feed magazine, each of the jigs configured to support a mask having apertures defining a pattern. A substrate is moved relative to a deposition source. The selected jig is transported into engagement with the substrate at a first location which is the mating position. The jig and substrate move in synchrony, while deposition material is passed through the apertures of the mask of the selected jig to develop the pattern of the deposition material on the substrate. The mask is disengaged relative to the substrate and the selected jig may be returned to the first location after the synchronous movement of the selected jig and the mask for repeated use of the jig. Alternatively, the selected jig may be transported to the feed magazine or other facility after use of the selected jig. The substrate and mask of the selected jig may be cooled during development of the pattern of the deposition material on the substrate. In some configurations, the masks of at least some of the plurality of jigs define patterns differing from the masks of others of the plurality of jigs.

The method may involve alignment of the substrate relative to the mask and/or alignment of mask relative to the substrate. For example, a position of the substrate and a position of the mask of the selected jig may be adjusted to provide alignment between the substrate relative to the mask. The position of the mask may be adjusted along one or two axes of the mask relative to the selected jig. The mask may be automatically tensioned relative to one or more axes of the mask. The alignment offset of a deposition cycle may be determined and used to adjust the alignment of the substrate and the mask for a subsequent deposition cycle.

The above summary of the present invention is not intended to describe each embodiment or every implementation of the present invention. Advantages and attainments, together with a more complete understanding of the invention, will become apparent and appreciated by referring to the following detailed description and claims taken in conjunction with the accompanying drawings.

### DESCRIPTION OF THE DRAWINGS

FIG. 1A shows a reciprocating aperture mask deposition system including a feed magazine in accordance with an embodiment of the invention;

FIG. 1B shows a reciprocating aperture mask deposition system including a feed magazine and an outfeed magazine in accordance with an embodiment of the invention;

FIGS. 2A and 2B illustrate an aperture mask having a pattern that defines a number of apertures that may be utilized in a deposition system in accordance with embodiments of the invention;

FIG. 3A is a top view of a jig/mask assembly in accordance with embodiments of the invention;

FIG. 3B illustrates a cross section view of a mechanism used for tensioning an aperture mask in accordance with embodiments of the invention;

FIGS. 4A and 4B show portions of a top and side view, respectively, of a single stage deposition system including an alignment section in accordance with embodiments of the invention;

FIGS. 4C and 4D illustrate side and cross section views, respectively, of an alignment transport mechanism and a shuttle mechanism as a jig/mask assembly is passed between an alignment section and a deposition chamber in accordance with one embodiment;

FIG. 5 is a block diagram of a system for controlling the position of the shuttle mechanism and controlling the tension and position of the substrate to assure proper alignment of the substrate and the mask in accordance with embodiments of the invention;

FIG. 6 illustrates markings that may be located on the substrate for purposes of controlling the lateral and longitudinal position of the substrate and maintaining proper registration between the substrate and the mask in accordance with embodiments of the invention;

FIG. 7 shows a position control system for a substrate in accordance with embodiments of the invention;

FIG. 8 is a diagram illustrating in more detail the tensioning aspect of the substrate transport system and substrate controller in accordance with embodiments of the invention;

FIG. 9A illustrates the use of a web location platform for supporting the substrate against the mask during deposition in accordance with embodiments of the invention;

FIG. 9B illustrates a support plate having a curved surface and an oscillating mechanism in accordance with an embodiment of the invention;

FIG. 9C illustrates a mechanism for injecting a gas between the substrate and a roller or drum in accordance with embodiments of the invention;

FIG. 9D illustrates a gas cooled support plate in accordance with embodiments of the invention;

FIG. 10 shows a deposition system having a web location platform moveable in the X direction in synchrony with the movement of the jig and mask during deposition in accordance with embodiments of the invention; and

FIGS. 11A and 11B are flowcharts conceptually illustrating a method for depositing material on a substrate in accordance with an embodiment of the invention.

While the invention is amenable to various modifications and alternative forms, specifics thereof have been shown by way of example in the drawings and will be described in detail. It is to be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION

In the following description of the illustrated embodiments, reference is made to the accompanying drawings that form a part hereof, and in which are shown by way of illustration, various embodiments in which the invention may be practiced. It is to be understood that the embodiments may be utilized and structural changes may be made without departing from the scope of the present invention.

Embodiments of the present invention are directed to systems and methods for depositing a pattern of material on a substrate. In accordance with the approaches described herein, aperture masks are mounted under tension in jigs that may be moved from a feed magazine and positioned relative to a substrate, such as an elongated web substrate. As denoted herein, substrate can mean any surface, including surfaces configured in a wound roll and fed so as to provide a longitudinal surface for coating. It is typical in the industry to refer to such elongated substrate as a web. The mask and web substrate are aligned prior to the deposition of material, such as through the use of markings, fiducials, and/or datums disposed on the substrate, mask and/or jig. The deposition material emanates from the deposition source, passes through apertures of the mask, and forms a pattern of deposition material on the web substrate corresponding to the aperture pattern.

Material may be deposited in one or more layers to form circuit elements and/or circuits, including combinations of conductors, resistors, diodes, light-emitting diodes (LEDs), capacitors, and/or transistors linked together by electrical connections. Thin film integrated circuits may include a number of layers of metals, insulators, dielectrics, and semiconductor materials. Thin film circuit elements may be created through deposition of patterned layers of these materials using systems employing reciprocating aperture masks as illustrated by the embodiments herein.

Deposition systems according to the present invention may include one or more of the features, structures, methods, or combinations thereof described in the embodiments below. For example, a deposition system may be implemented to include one or more of the advantageous features and/or processes described below. It is intended that such a system need not include all of the features described herein, but may be implemented to include selected features that provide for useful structures and/or functionality.

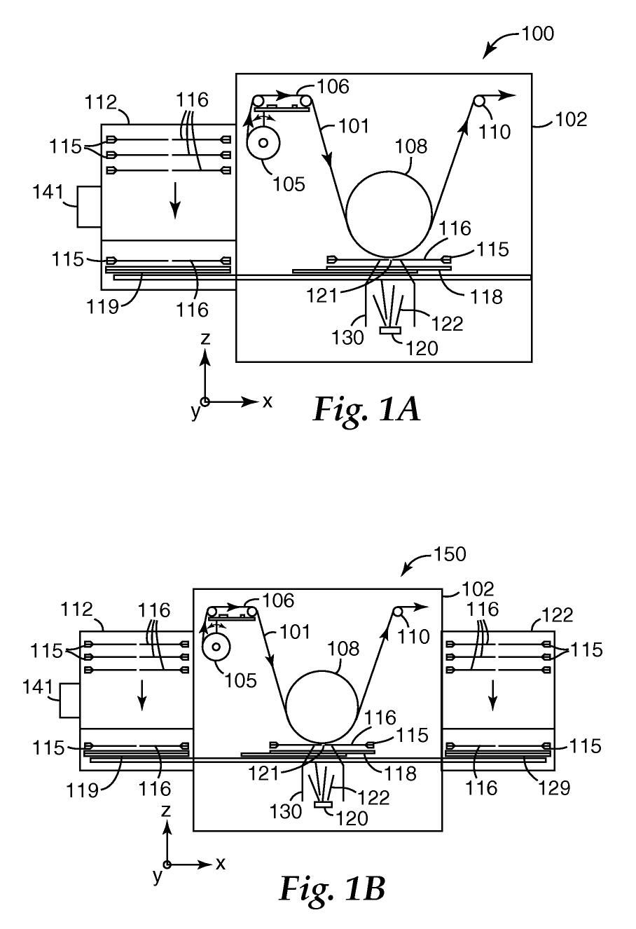

FIG. 1A shows a reciprocating aperture mask deposition system 100 in accordance with an embodiment of the invention. The deposition system 100 illustrated in FIG. 1A may be a first stage of a multiple stage deposition system. The deposition system 100 may accommodate mask designs for any layer of an electronic device, such as a thin film transistor (TFT) circuit, a matrix of light emitting elements used for a liquid crystal display, or a solar cell array. The deposition system 100 provides the capability to deposit all layers for these electronic devices and/or other electronic devices. A substrate transport mechanism is disposed within a vacuum chamber 102 to facilitate vacuum deposition of a material on a substrate 101. The substrate 101 is arranged on a unwind roller 105 that delivers the substrate 101 to the remainder of the deposition system 100. The substrate 101 travels over a first web guide 106, around a portion of a circumference of a rotating drum 108, over a second web guide or roller 110, and from there may continue to a further deposition stage.

The system 100 includes a feed magazine 112 configured to store a number of jigs 115 holding aperture masks 116 in tension. In the configuration shown in FIG. 1A, the jigs 115 are stacked vertically, although alternate arrangements of jig storage are envisioned. The feed magazine 112 includes a feed mechanism 119 for selecting jigs 115 and moving the jigs 115 from the feed magazine 112 into the vacuum chamber 102. Any jig 115 may be selected by the feed mechanism 119 for use in the deposition process. A temperature control unit 141, such as an infrared heater and temperature monitor, may be used to maintain a predetermined temperature within the feed magazine 112.

Once selected the jig 115 exits the feed magazine 112 and is received by a shuttle mechanism 118. The shuttle mechanism 118 reciprocates the X direction in line with the substrate 101 under the rotating drum 108 so that the aperture mask 116 held by the jig 115 is positioned between the substrate 101 and a deposition source 120.

The deposition source 120 is positioned under the drum 108 and emits deposition material 122 upward. The deposition material 122 passes through apertures in the aperture mask 116 and is deposited on the substrate 101. A shield 130 may be used to prevent material deposition in locations other than a desired region at the apex of the rotating drum 108. A shutter may be used to block the source material 122 from the substrate 101 to prevent premature deposition as the substrate 101 approaches the deposition position.

The deposition source 120 used depends on the type of deposition process and the type of deposition material desired. The deposition source 120 may be configured as a vacuum or non-vacuum deposition source capable of providing deposition material in liquid or gaseous form. In various implementations, the deposition material may be deposited by e-beam deposition, thermal evaporation, sputtering, chemical vapor deposition, including plasma enhanced chemical vapor deposition, spraying, printing, screen printing, or other types of deposition processes. In some deposition systems, multiple deposition sources are used.

As one example, the deposition source 120 may be a sputtering cathode or magnetron sputtering cathode for purposes of depositing metallic or conductive metal oxide materials. As another example, the deposition source 120 may be an evaporation source for purposes of depositing metallic or conductive metal oxide materials, conducting or semiconducting organic materials, dielectric inorganic or organic materials, electron-conducting materials, hole-conducting materials, or light-emitting materials.

In general, successive layers of a circuit or other component require layers of different materials from multiple deposition sources 120. More efficient machine utilization is achieved by coating successive materials which have similar deposition requirements, e.g., require similar vacuum levels, excitation levels, and heating methods. When using deposition sources having similar requirements, it is possible to make multiple depositions with the same mask 116, and/or within the same vacuum chamber without the need to move the substrate 101. Multiple sources 120 may be used to deposit multiple layers of material on the substrate 101.

The substrate 101 and the masks 116 may be made of various types of materials. Examples include polymeric materials, such as polyester (both poly(ethyleneterephthalate) (PET) and poly(ethylenenaphthalate) (PEN), polyimide, polycarbonate, polystyrene, metal foil materials, such as stainless steel, or other alloy steels, aluminum, copper, paper, woven or non-woven fabrics, or combinations of the above materials with or without coated surfaces. High density, small footprint electronic components can be produced by the deposition processes described herein.

As illustrated by the configuration of FIG. 1A, the drum 108, deposition source 120, jig/mask 115/116, and substrate 101 may be arranged so that the mask 116 and substrate 101 are positioned below the drum 108 with the deposition source 120 emitting the deposition material 122 upward. However, it will be appreciated that the mask 116 and substrate 101 may alternatively be positioned above the drum 108 while the deposition source 120 emits the deposition material 122 downward. This alternative configuration is particularly useful if an evaporation source is used.

The jig 115 and mask 116 may be moved across the deposition zone 121 during a deposition cycle and reciprocated back to a starting position for numerous subsequent deposition cycles. In some implementations, the mask 116 may be used for a number of depositions and then removed from the vacuum chamber 102 for disposal or cleaning.

FIG. 1B shows another embodiment of a deposition system 150. This embodiment is similar to FIG. 1A, except that an outfeed magazine 122 having an outfeed mechanism 129 is shown. After a mask 116 has been used for a number of deposition cycles, it is likely to have a significant buildup of deposition material necessitating cleaning or disposal of the mask 116. As illustrated in FIG. 1B, an outfeed mechanism 129 may be used to receive the jig 115 supporting the mask 116 from the shuttle mechanism 118. The outfeed mechanism 129 moves the jig 115 and mask 116 into the outfeed magazine 122 for storage, such as in a vertical stacked arrangement, or in any other convenient configuration. Upon reaching a predetermined fill level, the outfeed magazine 122 may be closed, sealed, and atmospheric pressure vented to the outfeed magazine 122. The stored jigs 115 and masks 116 may be removed from the outfeed magazine 122 for disposal or cleaning by another processing system (not shown).

The embodiment illustrated in FIG. 1B shows separate feed and outfeed magazines 112, 122, where the feed magazine 112 stores new or cleaned jigs/masks 115/116 that are ready to use in the deposition process and the outfeed magazine 122 stores used jigs/masks 115/116. In an alternate embodiment a single magazine may be used to store the jigs/masks 115/116 before and after cleaning.

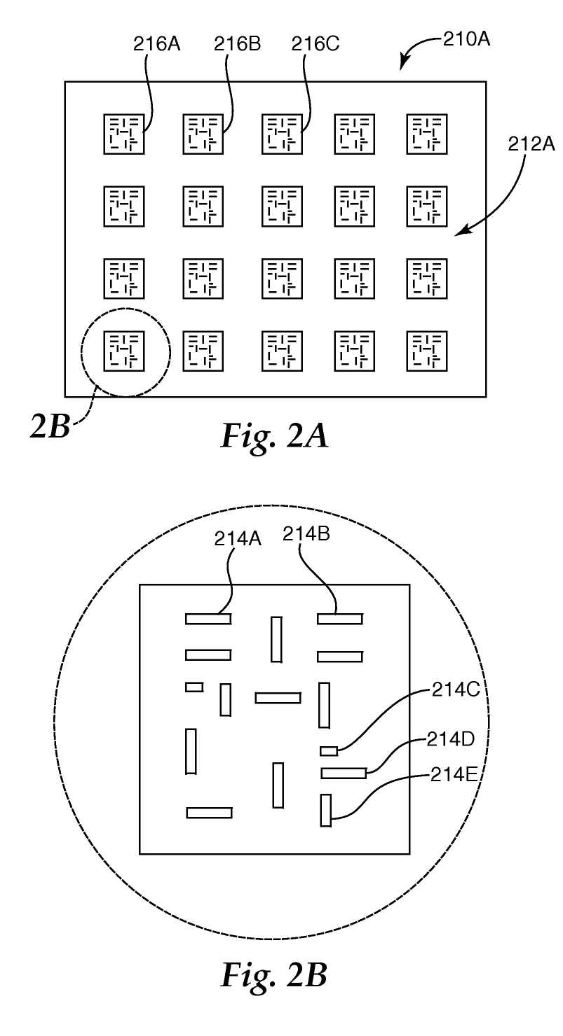

As shown in FIGS. 2A and 2B, an aperture mask 210A is formed with a pattern 212A that defines a number of apertures 214 (only apertures 214A-214E are labeled). The arrangement and shapes of apertures 214A-214E in FIG. 2B are simplified for purposes of illustration, and are subject to wide variation according to the application and circuit layout. Pattern 212A defines at least a portion of a circuit layer and may generally take any of a number of different forms. In other words, apertures 214 can form any pattern, depending upon the desired circuit elements or circuit layer to be created in the deposition process using aperture mask 210A. For example, although pattern 212A is illustrated as including a number of similar sub-patterns (sub-patterns 216A-216C are labeled), the invention is not limited in this respect.

Aperture mask 210A can be used in a deposition process, such as a vapor deposition process in which material is deposited onto a substrate through apertures 214 to define at least a portion of a circuit. Advantageously, aperture mask 210A enables deposition of a desired material and, simultaneously, formation of the material in a desired pattern.

Aperture mask 210A can be particularly useful in creating circuits for electronic displays, low-cost integrated circuits such as radio frequency identification (RFID) circuits, or any circuit that implements thin film components, including components comprising organic or inorganic semiconductors. Aperture mask 210A can be used to deposit small circuit features allowing the formation of high density circuits. Aperture mask 210A may be formed from a polymeric film such as by using laser ablation to define pattern 212A of deposition apertures 214. The formation and use of polymeric film aperture masks in deposition systems are further described in commonly owned U.S. Pat. No. 6,897,164, U.S. Patent Application Publication 20030151118, and U.S. patent application Ser. No. 11/179,418 (filed Jul. 12, 2005) which are incorporated herein by reference.

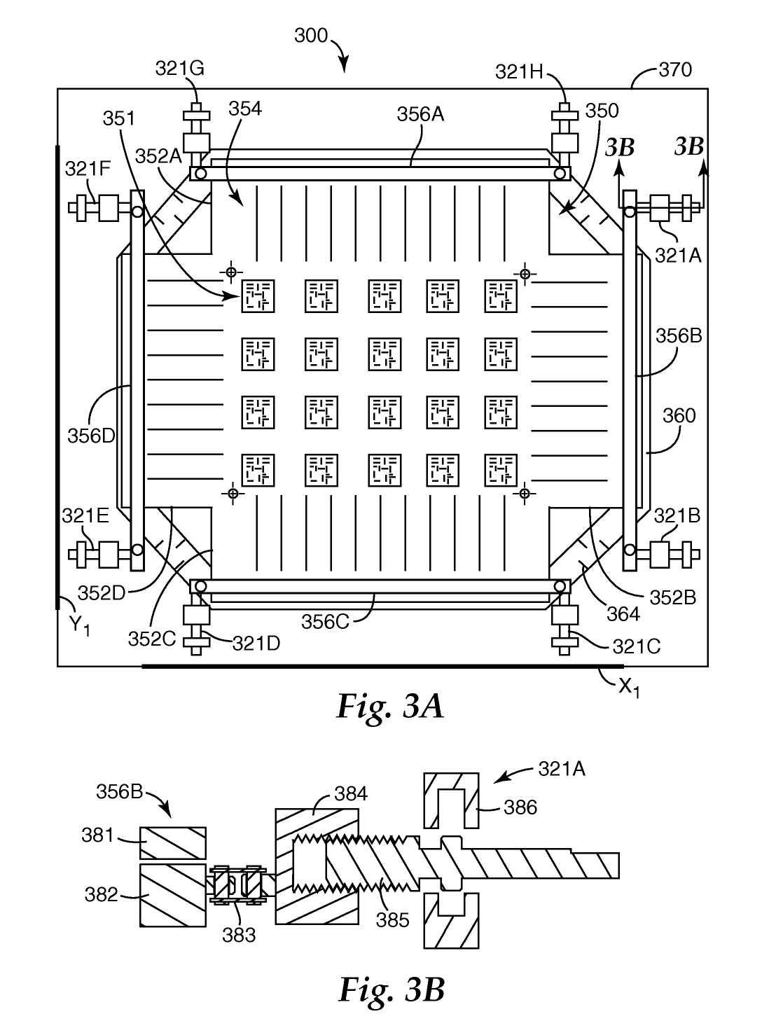

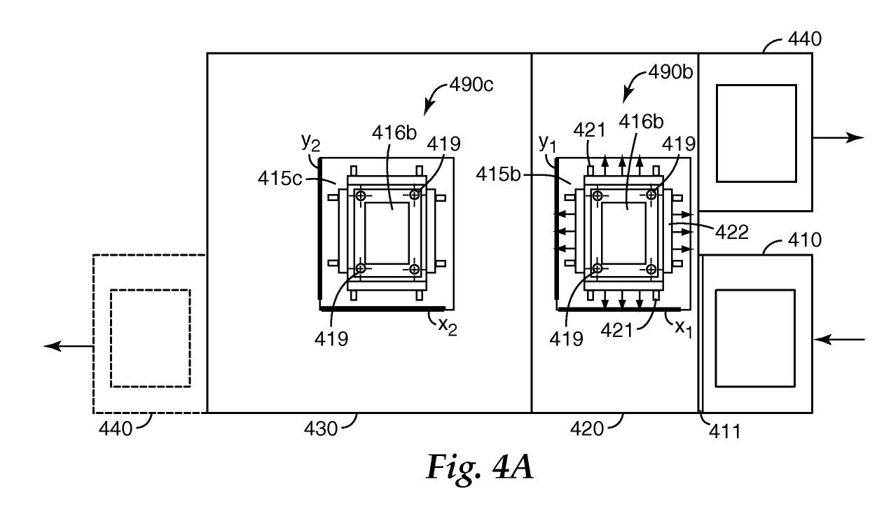

As previously described, the deposition system and method involves the use of aperture masks that are tensioned in jigs. FIG. 3A is a top view of a jig/mask assembly 300 that includes jig 370 and aperture mask 350. The aperture mask 350 has a pattern 351 formed as described above. The aperture mask 350 may be formed as a cross-shaped membrane having extension portions 352A-352D external to the pattern area 351. The extension portions 352A-352D of the mask 350 can be used to stretch the mask 350 to appropriately tension the pattern area 351 without distortion. The main cross shaped membrane of the mask 350 may comprise, for example, a metal or plastic frame 360 laminated onto a polyimide mask.

In one embodiment, the mask 350 is polyimide having a thickness of about 1 mil, and having a metal or a plastic frame 360 adhered to extension portions 352A-352D outside the pattern area 351. Extension portions 352A-352D and frame 360 facilitate manual mounting, clamping, and/or provide more uniform stress distribution.

Each extension portion 352 may include a set of distortion minimizing features 354, such as slits, which may be located near the edge of pattern area 351. Alternatively, or additionally, a set of stress relieving features 364 may be located on the frame 360. The distortion minimizing features 354 can facilitate more precise stretching of aperture mask 350 by increasing uniformity of pattern distortion of pattern 351 during stretching. Various configurations of distortion minimizing features 354 used for the mask include slits, holes, perforations, reduced thickness areas, and the like.

Clamps 356A-356D of jig/mask assembly 300 can be mounted on extension portions 352 or on the frame 360 of aperture mask 350. The jig 370 includes tensioning mechanisms 321A-321H attached to the clamps 356A-356D. In one embodiment, the tensioning mechanisms 321A-321H can be attached to micrometers mounted on an alignment fixture. In one embodiment, the tensioning mechanisms 321A-321H are coupled to tensioning motors (not shown) external to the jig 370. In FIG. 3A, each clamp 356 includes tensioning mechanisms 321, thus providing a total of eight degrees of freedom during stretching, although other arrangements providing more or fewer degrees of freedom are possible. Tension in the mask can be adjusted to provide a desired amount of stretching of aperture mask 350 and to facilitate proper alignment of the mask pattern 351 with the substrate. Edges of the jig 370 may be used as jig datums for aligning the mask relative to positions X₁ and Y₁.

FIG. 3B illustrates a cross section view of tensioning mechanism 321A and clamp 356B. The clamp 356B includes upper and lower clamp jaws 381, 382 that are arranged to grasp the aperture mask. Link 383 couples the lower clamp jaw 382 to a drive nut 384. Tensioning of the mask is implemented by rotating a lead screw 385 inserted into drive nut 384, converting rotational motion of the lead screw 385 into translational motion of the clamp 356B grasping the mask. Thrust bearing 386 prevents translational motion of the lead screw 385.

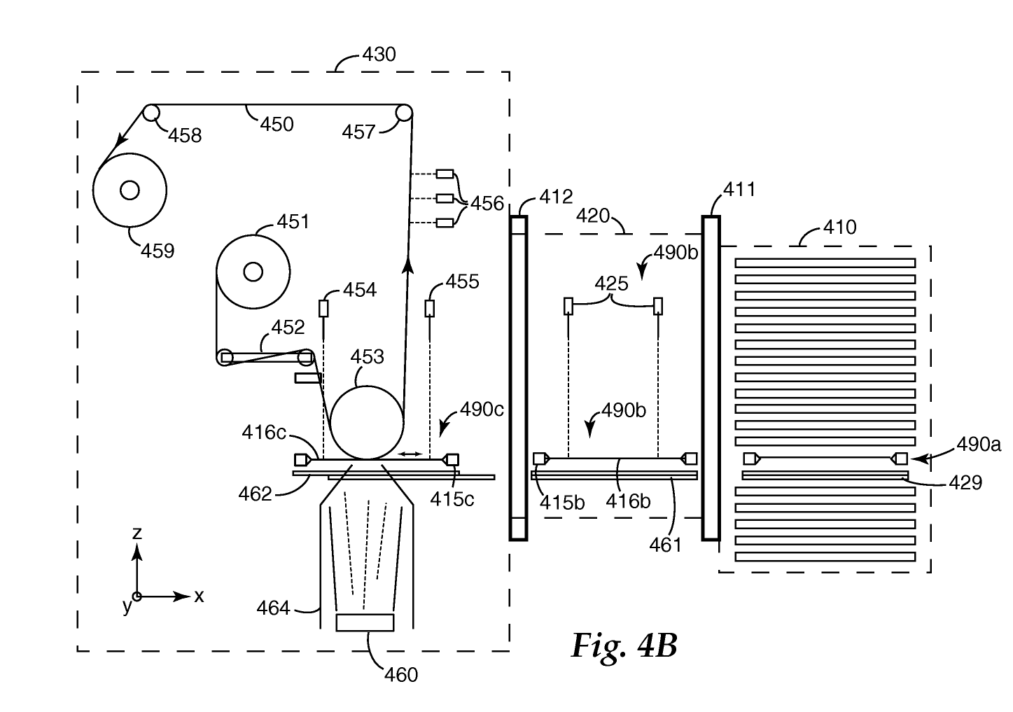

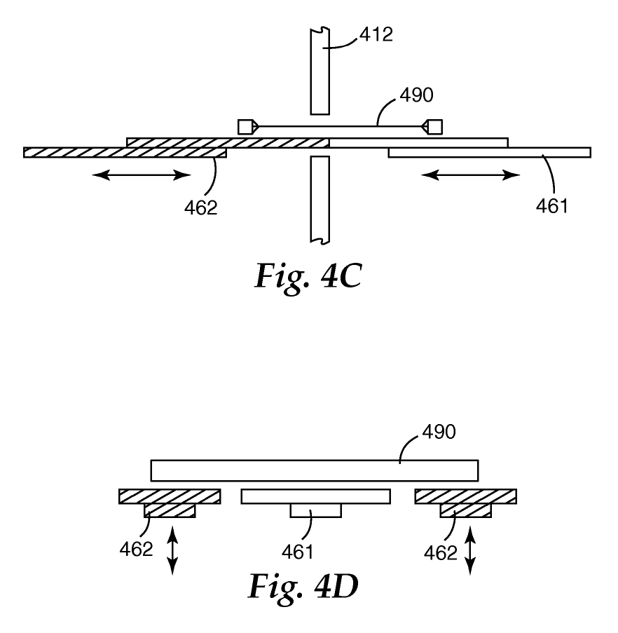

FIGS. 4A and 4B show portions of a top and side view, respectively, of a single stage deposition system in accordance with another embodiment of the invention. Referring first to FIG. 4A, the system includes a feed magazine 410 storing a number of jig/mask assemblies 490a, an alignment section 420, a vacuum deposition chamber 430, and an outfeed magazine 440. The outfeed magazine 440 may be located on the same side of the vacuum chamber 430 as the feed magazine 410, or may be optionally be located elsewhere, as indicated by the dashed lines showing an optional placement for the left-most outfeed magazine 440 in FIG. 4A.

FIGS. 4A and 4B show a jig/mask assembly 490b positioned in the alignment section 420 where the mask 416b supported by the jig 415b is being aligned. The jig/mask assembly 490b has been transported by the feed mechanism 429 and alignment transport mechanism 461 into the alignment section 420 from the feed magazine 410 through load lock 411. The jig/mask assembly 490b is moved by the alignment transport mechanism 461 to an alignment position defined by X₁ and Y₁ within the alignment section 420. As may be best seen in FIG. 4A, the alignment position is defined by hard stops for positioning edges of the jig/mask assembly 490b in the alignment section 420. When the jig/mask assembly is in the alignment position, with edges of the jig 415b against the hard stops at positions X₁ and Y₁, the edges of the jig 415b are used as datums to facilitate mask alignment.

The feed magazine 410 and/or the alignment section 420 may include temperature control units to condition the masks before, during and/or after alignment. As previously described, the tensioning mechanisms 421 on the jig clamps 422 are coupled to drivers (not shown), such as drive motors, or other movement mechanisms located in the alignment section 420 and outboard of jig 415b. Fiducials 419 on the mask 416 are located, such as by optical, magnetic, or capacitive sensors. FIG. 4B illustrates the use of optical sensors 425, e.g., a photodiode/photodetector sensor or camera, for fiducial alignment. In the tensioning process, the fiducials 419 on the mask 416b are adjusted to fall within a specified range from jig datums at locations X₁ and Y₁ in the alignment area. The mask 416b may be aligned with respect to one axis or may be aligned with respect to two substantially orthogonal axes.

In some implementations, the mask 416b is tensioned in both the X and the Y directions past the strain expected from heat induced in the mask 416b by the deposition process. Force transducers may be coupled to the mask 416b and/or jig 415b to provide feedback for tension control. The tensioning process may also take into account individual mask geometry effects on pattern movement under strain to enhance deposition alignment over previously deposited patterns. The mask 416b may be placed under tension for a strain soak period. Alignment of the mask fiducials 419 with the datums provides an alignment XY location for a fully strained mask 416b.

The alignment process may be facilitated by computer with closed loop feedback control involving all global fiducials 419 on the mask 416b. In some implementations, at least one of the clamps 422 may be non-rigid, and may be configured as a segmented clamp assembly. The tensioning drivers may manage the position of each clamp segment. The use of segmented clamps with associated tensioning drivers provides the ability to strain mask segments to affect complimentary portions of the mask 416b. The use of a segmented clamp allows for enhanced uniformity of fiducial alignment distributed across the mask area.

After tensioning, the jig/mask assembly 490b is moved from the alignment section 420 through load lock 412 and into the deposition chamber 430. Within the deposition chamber 430, a substrate transport mechanism includes driven unwind and wind rollers 451, 459, web guide 452, rollers 457, 458, and other substrate transport components. The substrate 450 is delivered from unwind roller 451, traveling over a web guide 452 and around a portion of a circumference of a rotating drum 453. The substrate 450 continues from the rotating drum 453, passes over rollers 457, 458 and is collected on wind roller 459.

In the deposition chamber 430, the jig/mask assembly 490c reciprocates under the rotating drum 453 so that the aperture mask 416c is positioned between the substrate 450 and the deposition source 460 during deposition. A shield 464 may be used to prevent material deposition other than in a desired region at the apex of the drum 453.

In one embodiment, the shuttle mechanism 462 is capable of positioning the jig 415c and mask 416c in X, Y, and Z directions prior to deposition. Angular placement (ø) of the jig/mask assembly 490c may also be accomplished via the shuttle mechanism 462. The shuttle mechanism 462 may also be used to move the jig/mask assembly 490c across the coating field during deposition. As the jig/mask assembly 490c enters the deposition chamber 430, the shuttle mechanism 462 receives the jig/mask assembly 490c and moves the jig/mask assembly 490c into the mating position beneath the drum 453. Through the use of sensors 454-455, the mask 416c is positioned in the mating position based on alignment of the mask fiducials with respect to jig datums at positions X₂ and Y₂. In timed sequence with an incoming substrate pattern, the jig/mask assembly 490c is moved into contact with the incoming substrate 450 and deposition begins. If a shutter is used it is opened prior to deposition. At the end of the deposition, the optional shutter is closed and the jig/mask assembly 490c is displaced in the negative Z direction departing from the substrate.

Alignment of the substrate 450 and the mask 416c in the Y direction may be accomplished by moving the substrate 450 to an absolute Y position using markings on the substrate 450, and then moving the mask 416c via the shuttle mechanism 462 to the same Y position using fiducials 419 on the mask 416c. The markings and/or fiducials may be formed by any process that provides a discernable reference, such as through deposition of material, removal of material to create openings or voids, trimming an edge, and/or by changing the physical, optical, chemical, magnetic or other properties of a material to produce a reference.

Initial alignment in the X direction may be accomplished by timing the movement of the shuttle mechanism 462 when the substrate pattern is moving into the mating position. The shuttle mechanism 462 moves the mask 416c into the mating position prior to the mask making contact with the substrate 450 by timing the incoming pattern from an upweb location to the mating position. Cyclic marks on the substrate 450, sensed by sensors 456, may be used to enable this timing and alignment process. Likewise, it is possible to delay the incoming substrate 450 while the shuttle mechanism 462 traverses back into the mating position. Additionally, it is possible to space the patterns first coated on the substrate 450 such that returning the jig/mask assembly 490c to the mating position is possible without delaying the substrate timing. The shuttle mechanism 462 then moves the jig/mask assembly 490c in the +Z direction for contact between the substrate 450 and the mask 416c. After initial alignment and subsequent depositions on the substrate, feedback from sensor systems 456 downweb of the coating area allows for correction of the alignment at the mating position. Sensors 454-456, such as cameras and/or photodetectors, can be used to report alignment information from previous deposition cycles and the feedback information may be used by software and circuitry to adjust the mating position for subsequent cycles. This allows the system to correct the offset error using information from previous deposition cycles and/or fiducial locations, such as by averaging or other methods. Software and circuitry may be configured to avoid over-correcting, cause “hunting” control behavior, or otherwise disrupt the smooth functioning of the other X and Y positioning systems.

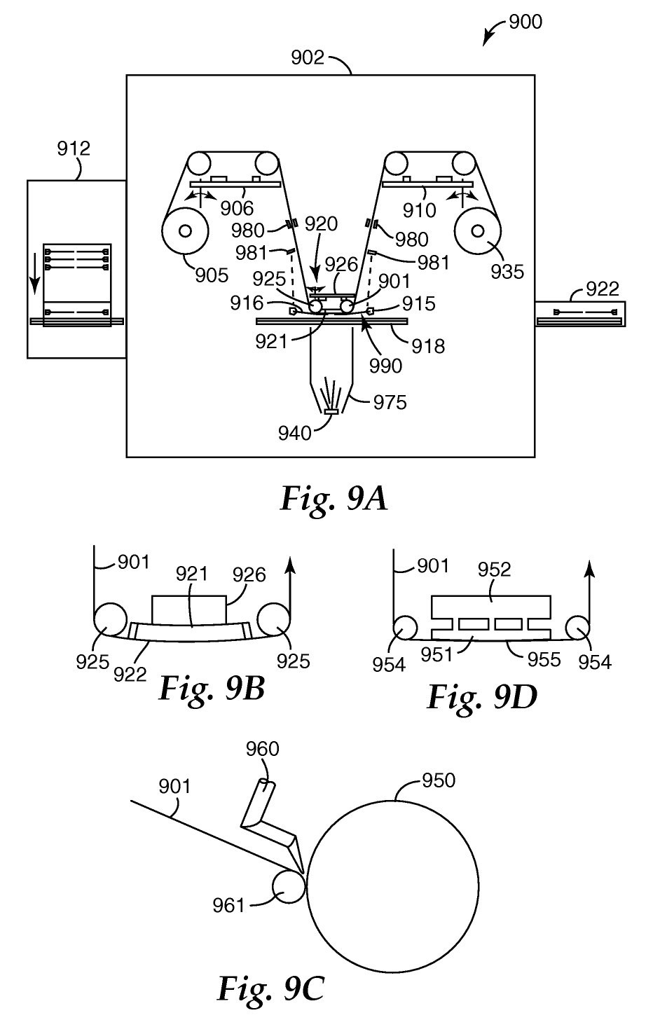

In some embodiments, the drum 453 may be replaced by a web location platform which may be used to align the mask 416c and the substrate 450. A web location platform may be used alone, or in conjunction with the shuttle mechanism 462 for alignment of the mask 416c and the substrate 450. These configurations are more fully described below in connection with FIG. 9A. The approaches for alignment and timing of the substrate 450 and mask 416c are provided herein as exemplary approaches. Other techniques for providing for alignment and movement of the mask 416c in synchrony with substrate patterns are considered to be within the scope of this invention.

During deposition, the substrate 450 and mask 416c are brought into contact and may be moved together or independently by the shuttle mechanism 462 in the X direction past the coating field. At the end of each X direction traverse, the mask 416c and substrate 450 are separated, such as by the shuttle mechanism 462 dropping the jig/mask assembly 490c in the −Z direction to achieve a predetermined clearance from the substrate 450. The shuttle mechanism 462 then moves the jig/mask assembly 490c back to the mating position where the mask 416c mates with the substrate 450 in alignment. Successive depositions involve repeated, timed alignment of the mask 416c and substrate 450 with each incoming substrate pattern. In this way, it is possible for near continuous substrate motion to proceed while the reciprocating shuttle mechanism 462 repeatedly moves the jig/mask assembly 490c to the mating position after each pattern deposition. Appropriate spacing between substrate patterns allows time for the reciprocating action of the shuttle mechanism 462 and adequate alignment time.

FIGS. 4C and 4D illustrate side and cross section views of the alignment transport mechanism 461 and the shuttle mechanism 462 as the jig/mask assembly 490 is passed through the load lock 412 in accordance with one embodiment. FIG. 4C illustrates the side view of the opened load lock 412 with the jig/mask assembly 490 being passed from the alignment transport mechanism 461 to the shuttle mechanism 462. FIG. 4D is a cross section view of the jig/mask assembly 490, shuttle mechanism 462, and alignment transport mechanism 461. A portion of the alignment transport mechanism 462 supporting the jig/mask assembly 490 fits between dual rails of the shuttle mechanism 461. The shuttle mechanism 461 is moveable in the +/−Z directions to lift the jig/mask assembly 490 from the alignment transport mechanism 461.

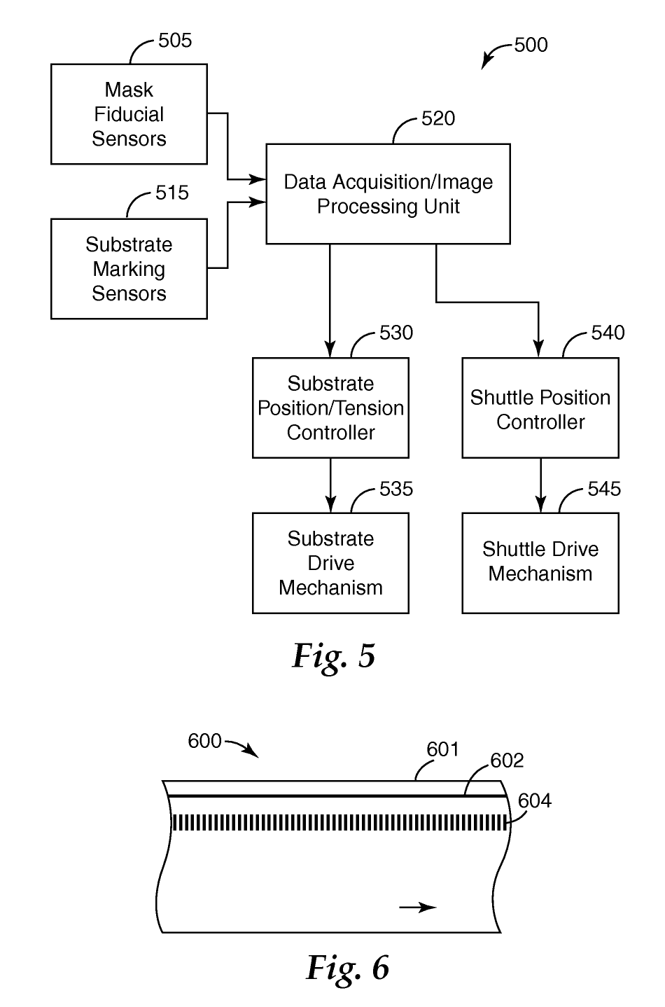

FIG. 5 is a block diagram of a system 500 for controlling the position of the shuttle mechanism and controlling tension and position of the substrate to assure proper alignment of the substrate and the mask. The control system 500 may include one or more sensors 505, 515 used to determine the position of the jig/mask assembly and the substrate. As previously discussed, alignment of the mask with the substrate in the Y direction may be implemented using markings on the substrate and fiducials on the mask. Sensors 505, such as cameras, photodetectors, and/or other type sensors provide mask fiducial position information to an image data acquisition unit 520.

Down-web timing, location and/or lateral (cross web) positioning of the substrate may be accomplished using markings disposed on the substrate. The substrate markings may comprise cyclic marks, lines, voids, trimmed web edges, or any other reference used to determine the position of the substrate. Longitudinal markings, which can be cyclic marks, may be used for determining the down-web (X direction) location of the substrate. They can be used in timing the arrival of substrate patterns in synchrony with the mask. Lateral markings, which may be a line in the margin of the substrate or a trimmed substrate edge, are useful for controlling the lateral position of the substrate. Substrate marking sensors 515 may include separate sensors for detecting the lateral markings and the longitudinal markings. Signals generated by the substrate marking sensors 515 are received by the data acquisition/image processing unit 520 which may digitize and/or process the sensor signals.

The data acquisition/image processing unit 520 is coupled to a substrate position/tension controller 530 and a shuttle position controller 540. The shuttle position controller 540 receives information produced by the data acquisition/image processing unit 520 and outputs signals to the shuttle drive mechanism 545 to position the jig/mask assembly during the deposition process.

The substrate position/tension controller 530 receives information produced by the data acquisition/image processing unit 520. The substrate position/tension controller 530 uses the position information from the data acquisition/image processing unit to control the substrate tension, X direction position, and lateral position of the substrate via the substrate drive mechanism 535.

In some implementations, the control system 500 controls the placement of the mask pattern relative to a previously deposited pattern on a moving substrate. Each subsequent placement of the mask can involve placement relative to a new and slightly different pre-deposited pattern to form multiple layer depositions.

The control system 500 may be configured to be adaptive, learning from the last error in placement relative to the fiducial targets to more accurately place the mask for the each successive deposition. The control system 500 learns by taking into account the alignment error information of one or more previous cycles received from the data acquisition/image processing unit 520. On the next cycle, the jig/mask assembly is positioned relative to the substrate using the alignment error information generated from one or more previous cycles. The process is repeated until the error is sufficiently reduced. By reducing the error, the process becomes fully adapted and deposition occurs within acceptable tolerance limits.

FIG. 6 shows an example of the markings that may be located on the substrate for purposes of controlling the lateral and longitudinal position and maintaining proper registration between the substrate and the mask. These markings may be pre-patterned or may be added to the substrate during a first stage of the deposition process.

As shown in this example, the lateral or crossweb marking may be a line 602 that is a fixed distance from the location of deposition patterns to be formed on the substrate 600. An edge 601 of the substrate 600 may not be located in a precise relationship to the line 602 or any deposition patterns on the substrate 600. However, a web edge trimmed or marked for this purpose may be used for substrate alignment. From sensing the location of the line 602 in the lateral direction, it can be determined whether the substrate 600 is in the proper location or whether a web guide adjustment is necessary to realign the substrate in the lateral direction.

As is also shown in this example, the longitudinal or machine direction substrate markings may be a series of cyclic marks 604 spaced a fixed distance from one another in the machine direction. From sensing the position of a cyclic mark 604 in the series, it can be determined whether the substrate 600 is at the proper longitudinal position relative to deposition patterns on the substrate 600 at a given point in time.

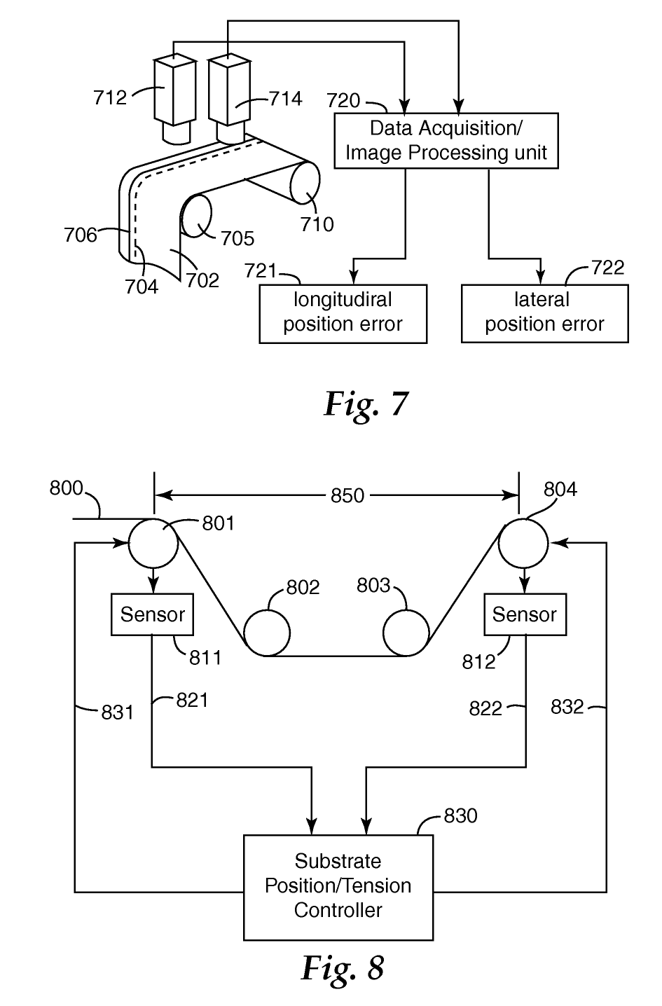

FIG. 7 shows an illustrative embodiment of a position control system for a substrate. In this embodiment, one sensor is being used for the lateral position control while another sensor is being used for the longitudinal position control. The substrate 702 has a linear marking 706 for longitudinal position control and cyclic markings 704 for lateral position control. As the substrate 702 passes between roller 705 and roller 710, the longitudinal sensor 712 senses the line 706 while the lateral sensor 714 senses the cyclic markings 704. The longitudinal and lateral sensors 712, 714 may be implemented using a light emitting diode (LED) and photodetector circuit, or a CCD camera, for example.

The output from the longitudinal sensor 712 is provided to the data acquisition/image processing unit 720 which determines the longitudinal error in the substrate position 721, i.e., how far the actual location of the longitudinal fiducial marking is from the expected location. The position error for the longitudinal direction 721 is output to the substrate position controller (530 of FIG. 5).

The output from the lateral sensor 714 is provided to the data acquisition/image processing unit 720. The image processing unit 720 determines the error in the lateral position of the substrate, i.e., how far the actual location of the lateral fiducial marking is from the expected location. The position error 722 for the lateral or crossweb direction is output to the substrate position controller (530 of FIG. 5).

Deposition of small geometry regions on the substrate requires precise control of the substrate position as well as the tension in the substrate. If the substrate is improperly tensioned, it may sag causing inaccuracies in deposition location. The substrate controller (530 of FIG. 5) controls position and tension in the substrate within the substrate transport system. FIG. 8 is a diagram illustrating in more detail the tensioning aspect of the substrate transport system and substrate controller. In this particular example, a segment of a substrate transport system, which is typically referred to as a tension zone 850, is shown containing two driven rollers 801, 804 and a number of idler rollers 802, 803 that move the substrate 800 through the substrate transport system. The driven rollers 801, 802, which may comprise unwind and wind rollers as illustrated in previous figures, are coupled to drive motors that rotate to move the substrate 800 at a desired speed or to effect a displacement of the web substrate longitudinally. A substrate position/tension controller 830 collects substrate position data from sensors 811, 812 that indicate the position of the substrate 800. In some implementations the sensors 811, 812 may comprise the longitudinal sensors previously described.

In other implementations, the sensors 811, 812 may comprise encoders coupled to the driven rollers which provide data relating to the rotation of the rollers 801, 804. Because the rollers 801, 804 rotate in direct proportion to the amount of web material that has passed through a roller, data from these sensors 811, 812 may be obtained that indicates the amount of substrate web 800 added to and subtracted from the tension zone 850 between the two driven rollers 801, 804.

During operation, the substrate 800 unwinds into the tension zone 850 from the left from the first roller 801 having associated position sensor 811. Second and third undriven rollers 802, 803 are idler rollers, i.e., undriven rollers, used to obtain a desired physical web path configuration through the substrate transport system. A fourth roller 804 is located at the exit of this tension zone 850, and also has an associated position sensor 812. Any of these rollers 801-804 may be driven, although in a typical configuration only the entering and exiting rollers, or wind and unwind rollers, would be driven. In addition, any or all of these rollers may be idler rollers while still operating according to principles of the invention. While only two idler rollers 802-803 are shown, any number of rollers may be used to obtain the desired web path configuration.

The substrate controller 830 receives positions signals 821, 822 from position sensors 811, 812, and calculates various parameters of substrate material 800 within tension zone 850 in real-time based on the signals. For example parameters, such as web tension, elastic modulus, thickness, and width, may be accurately determined in real-time. High-resolution position sensors produce position signals 821-822 that allow controller 830 to accurately determine the changes in position of driven or undriven substrate transport rollers 801 and 804. Substrate controller 830 may then accurately determine the feedback data for use in real-time control of substrate transport system.

More specifically, based on position signals 821, 822 received from the position sensors 811, 812, the substrate controller 830 determines the amount of substrate 800 that has been added to and subtracted from the web zone 850 during any given sample period. From a prior determination of the amount of substrate material 800 in the tension zone 850 at the start of the sample period, the substrate controller 830 determines the amount of substrate material 800 in the tension zone at the end of the sample period. Because the span of the tension zone 850 is both fixed and known, substrate controller 830 determines the amount of strain in substrate material 800 from these data values. Once a current measurement of strain in the substrate is determined, other substrate parameters may be easily determined, such as tension, modulus, elastic modulus, thickness, and width.

Based on the determined parameters, substrate controller 830 controls actuator control signals 831, 832 in real-time. For example, actuator control signal 831 may control a drive motor (not shown) of roller 801. Similarly, actuator control signal 832 may control a drive motor (not shown) of roller 802. As such, substrate controller 830 may control roller 801 as a mechanism to control the tension in the web material 800 within tension zone 850. Further details of tension control processes which may be utilized in conjunction with embodiments of the present invention are described in commonly owned U.S. Patent Application Publication US 20050137738 which is hereby incorporated herein by reference.

FIG. 9A shows another configuration for a deposition system 900 in accordance with an embodiment of the invention. The deposition system of FIG. 9A includes a feed magazine 912, an outfeed magazine 922 and a deposition chamber 902, as previously described. The substrate 901 is moved through the deposition chamber 902 on a substrate transport system including an unwind roller 905, a first and second web guide 906, 910, and a wind roller 935. A jig/mask assembly 990 is reciprocated by a shuttle mechanism 918 under a web location platform 920. The web location platform 920 supports the substrate 901 against the mask 916 which is tensioned in the jig 915.

The deposition system 900 may include the thermal protection of an integral shield 975 mounted around all non-patterned areas of the jig/mask assembly 990. The use of a shield 975 enables minimal thermal influence from support structures heated inadvertently by stray deposition of coating materials and minimizes subsequent cleaning requirements.

The use of the web location platform 920 to support the substrate 901 against the mask allows deposition over a wider area than is practical using the rotating drum previously described. For example, a coating apparatus may have a substantially wide flat field for deposition of source material at a nearly normal angle. The web location platform 920 allows a wide field to be coated without the encumbrances of a very large roll.

In one embodiment, the web location platform 920 may be configured to have the capability of movement in X, Y, Z, and/or ø directions to facilitate position adjustment of the substrate. The alignment accomplished via the web location platform 920 may be used as an alternative to or in addition to alignment capability of the reciprocating shuttle mechanism 918. The use of both the web location platform 920 and the shuttle mechanism 918 for alignment of the mask 916 and substrate patterns provides increased flexibility in alignment for any combination of mask fiducials/substrate markings, sensors, and materials. In some configurations, the web location platform 920 may have the ability to move in X, Y, Z, and/or ø directions in minute increments for accurate positioning of the substrate to the moving mask up to but not during coating.

In one implementation, no movement of the substrate 901 or mask 916 occurs during deposition. Prior to deposition, the web location mechanism 920 may be configured to allow angular (ø), X and/or Y direction motion in order to align and synchronize the mask 916 with upcoming, pre-coated substrate patterns. In another implementation, after alignment, once contact between the substrate 901 and mask 916 is made, the substrate 901 and jig/mask assembly 990 move in synchrony during deposition while the web location platform 920 remains motionless. After deposition, the substrate 901 and the mask 916 can be separated either by retraction of the web location platform 920 upwards and/or by retraction of the mask 916 downward.

The deposition system 900 may include shuttle position controller logic for monitoring mask fiducials to provide a positional correction of the shuttle mechanism 918 to facilitate the overall mask pattern alignment with an incoming substrate pattern. Optical sensors or cameras 981 monitor the location of mask fiducials relative to predetermined locations. Data acquired from the monitoring operation is sent to a software driven shuttle position controller. The controller makes appropriate calculations, and outputs a correction for ø, X, and/or Y for the next successive placement of the reciprocating shuttle mechanism 918 and mask 916. The shuttle position controller logic also receives and uses information from substrate marking sensors 980 regarding the movement and position of the substrate pattern coming into the mating position. Using this approach, misaligned patterns can be stepped into position over a series of deposition cycles. The misalignment may be corrected relatively quickly to limit the number of inaccurately placed patterns.

The use of a reciprocating mask 916 for deposition may be extended to the use of multiple patterns per mask and/or deposition by multiple sources. The reciprocating mask 916 is particularly useful when multiple materials from multiple deposition sources can be deposited using the same mask 916. Placement of the mask only once enables better utilization of the deposition equipment. The deposition source 940 illustrated in FIG. 9A may represent two or more deposition sources.

Portions of the web support platform 920, including rollers 925 and support plate 921, are shown in more detail in FIG. 9B. FIG. 9B illustrates a curved support plate 921 for supporting the substrate 901, which may be used, for example, in deposition systems such as those previously illustrated. Portions of the internal body of the support plate 921 may be formed of a porous material to facilitate gas injection through the support face deposed towards the substrate 901. Injection of a gas, such as argon, may be used for cooling the support plate 921, substrate 901, and mask during deposition. In addition, gas injection may be alternatively or additionally used to facilitate frictional release of substrate 901 from the support plate surface 922. In addition, a mechanism 926 for oscillating the support plate 921, such as a piezoelectric oscillator, could be incorporated into the mechanical support allowing movement of the support plate 921 in the radial or Y directions at high frequency. Such movement enables a large reduction in the frictional characteristics of the support plate/substrate system and can enable smooth, sliding motion without the needed for lubricious coatings on the face of the support plate 921. The use of oscillating mechanisms for support plate applications are further described in U.S. Pat. No. 4,451,501 which is incorporated herein by reference. Rollers 925 may be used in web support roles or not used depending on the path required.

Some level of roughness of the support plate surface 922 may be used for supporting the substrate 901 against the mask and may reduce sticking between the substrate 901 and the surface 922. Use of a support plate 921 having a degree of surface roughness disposed towards the substrate 901 advantageously accommodates substrate support and may also enhance uniform gas flow in the gas cooled plates described below.

The surface 922 disposed towards the substrate 901 may be textured, as through microreplication, machining and peening, grinding, or embossing, for example. Forming the surface from a ceramic, a specialty polymer, or a polymer composite instead of a metal may also discourage sticking. Specialty polymer or polymer composite coatings can be used to provide an appropriate amount of surface roughness to accommodate reduced sticking. For example, a fluoro-polymer or composite thereof with ability to also conduct electrically and thermally may be advantageous. Additionally, use of a substrate, for example, with a controlled level of roughness on one side may be used to prevent sticking between the substrate and support surface. Another approach to prevent the substrate from sticking involves a lubricious surface treatment applied to the plate, such as NEDOX SF-2, MAGNAPLATE HMF, ARMOLOY, NYFLON, DICRONITE, or other such products. Slip agents like calcium carbonate and other materials used in the manufacture of extruded polymer films may be used to enhance handling the substrate and provide the right degree of friction on a sliding contact surface. Various materials may be applied to the substrate surface or integrated into the components of the substrate to accommodate thermal transfer.

Sticking between the substrate and the surface of a drum, plate, or other object used to support the substrate against the mask may be reduced through the injection of a gas between the substrate and the surface of the supporting object, as illustrated in FIG. 9C. As shown in FIG. 9C, the substrate 901 travels over roller 961 and under a circumferential portion of a rotating drum 950. A gas injection nozzle 960 injects bursts or a continuous flow of gas between the substrate 901 and the surface of the rotating drum 950 to enhance thermal transfer and to prevent sticking.

FIG. 9D illustrates an embodiment including a gas cooled support plate 951 positioned between rollers 954 that may be used, for example, in deposition systems described herein. As illustrated in FIG. 9D, support plate 951 is used for supporting the substrate 901 against the mask (not shown). The surface 955 of the support plate 951 disposed towards the substrate can be porous. A gas manifold 952 disposed behind the plate 951 allows bursts or a continuous flow of gas between the substrate and the plate surface 955 to cool the substrate 901 and mask. Additionally, both rollers 954 may be cooled.

The system of two rollers 954, support plate 951, and gas delivery manifold 952 illustrated in FIG. 9D allows the continuous web substrate 901 to be cooled and transported without scratching the substrate. The cooled support plate 951 provides a support for the mask (not shown) as the combination of mask and substrate move together past the coating field during deposition.

The gas delivery manifold 952 and supporting gas system may be configured to supply a sufficient volume of gas, e.g. argon, or other inert gas between substrate 901 and support plate 951 to enhance heat transfer during deposition. It is advantageous to provide such cooling to prevent mechanical deformation of the mask and/or substrate as the heat produced by the deposition process is absorbed. Depending on the speed and thickness of deposition, the deposition process can cause heating near the glass distortion temperature of the polymers in the substrate 901 and/or the mask. Such heating can cause permanent strain and deformation. Additionally, the gas layer provides a synergistic near frictionless support to the substrate moving past the tension plate 951. In some embodiments a support plate including a gas delivery manifold, as illustrated in FIG. 9D, may be used in conjunction with an oscillating mechanism as illustrated in FIG. 9B.

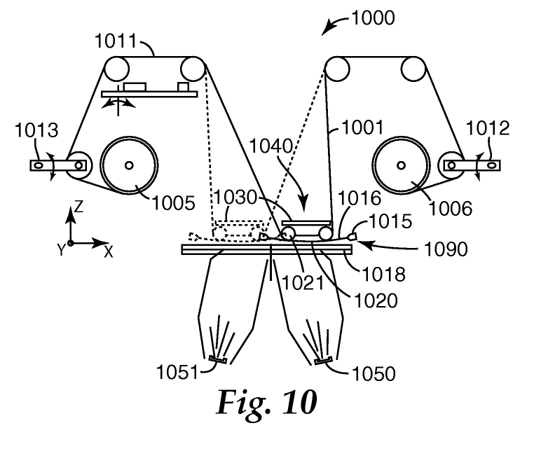

FIG. 10 shows a deposition system 1000 having a web location platform 1040 that is moveable in the X direction in synchrony with the movement of the jig/mask assembly 1090 during deposition to allow a larger area and/or longer time and/or increased distance for deposition, such as for significantly increased thickness and/or larger area of deposition. FIG. 10 illustrates the use of a first deposition source 1050, and, optionally, one or more additional sources 1051.

The substrate transport system includes unwind roller 1005, wind roller 1006, and web guide 1011. The substrate transport system may further include minimal movement dancers 1012 and 1013 to enhance tension and X direction location control of the substrate 1001. A plate 1020 supports the substrate 1001 against the mask 1016.

The web location platform 1040 of the deposition system 1000 may be suitably mounted so as to facilitate movement of the web location platform 1040 in synchrony with the jig 1015 and mask 1016 during deposition. FIG. 10 shows the start (dashed lines) and finish (solid lines) positions of the web location platform 1040 during a cycle of the deposition process. In one implementation, the web location platform 1040 includes a chilled plate 1020 and rollers 1021 which are mounted on a table 1030 that can be moved in the X, Z, and ø. At the start of the cycle, the web location platform 1040 drops down in the −Z direction onto the mask 1016 at start (mating) position. The web location platform 1040, including the table 1030, support plate 1020, and rollers 1021 move in synchrony with the jig 1015 and mask 1016 above the deposition source 1040 to the finish location. At the finish location, the web location platform 1040 moves in the positive Z direction, disengaging the substrate 1001 from the mask 1016. The web location platform 1040 reciprocates back in synchrony with the jig/mask assembly 1090 to the mating position in preparation for another deposition cycle. In some embodiments, the mask/jig assembly 1090 is moved by the shuttle mechanism 1018 in the Z direction to facilitate engagement and disengagement of the mask 1016 and the substrate. In similar fashion, the ø adjustment can be implemented by either or both the web location platform 1040 and the shuttle mechanism 1018. The web guide 1011 may be used to guide and locate the substrate in the Y direction prior to a pattern reaching the mating position.

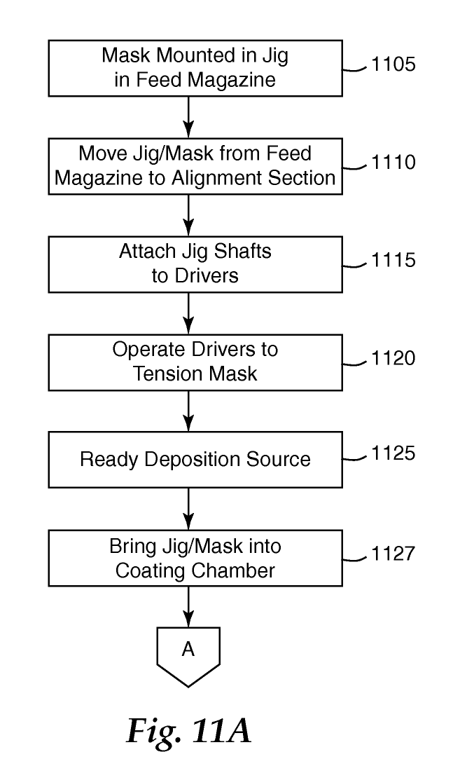

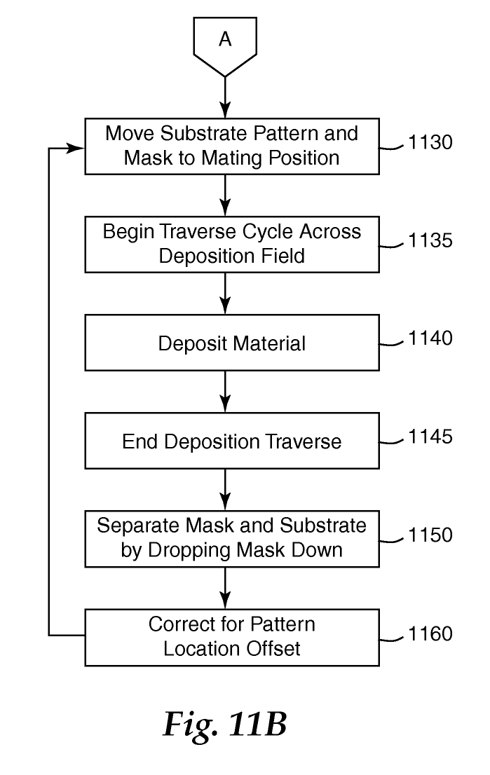

FIGS. 11A and 11B are flowcharts conceptually illustrating a process for deposition using a reciprocating aperture mask that may be used for making electronic devices, such as an array of thin film transistors, on a substrate in accordance with an embodiment of the invention. The blocks shown in the FIGS. 11A and 11B represent exemplary process steps that may be used for deposition of materials on a substrate using a reciprocating aperture mask. Implementation of the deposition process need not occur in accordance with the specific order of the blocks illustrated in FIGS. 11A and 11B and the process steps may occur in any order and/or some process steps may occur simultaneously with other process steps.

Turning now to FIG. 11A, an aperture mask 1105 is mounted in a jig positioned within a feed magazine. The aperture mask may be formed, for example, using laser ablation wherein a thin, polyimide sheet is patterned with a fine pattern corresponding one layer of, for example, a TFT. Such a pattern on polymer film is described as a polymer shadow mask (PSM). The PSM is designed to be placed against any substrate as a stencil to coat the substrate only in the areas ablated open. In this form the PSM may be quite fragile. The PSM is designed in such a way that it can be placed into a flexible polymer stiffening frame. For example, the PSM maybe laminated to such a frame, which may be fabricated such that the frame fits cleanly into a clamping system. In some circumstances, the pattern design requires the PSM to be ablated with extra openings at strategic places in the mask pattern areas inside and/or outside of the deposition area. These extra openings are strategically placed to compensate for thermal heating and stress relaxation. Such openings may be in the form of slits, rectangles or other geometric shapes including sub-patterns of those in the main mask pattern itself.

A set of such masks is respectively mounted into a set of alignment jigs. The jigs include shafts for tensioning the masks within the jigs. Each mounted mask can have the same pattern or a different pattern from other masks in the set, depending on the strategy for manufacturing a particular device. This set of jig/mask assemblies is placed into the feed magazine stack of a vacuum deposition system.

A jig/mask assembly is moved 1110 in automated fashion from the feed magazine into an alignment position within the alignment section. Shafts of the jig are attached 1115 to machine drivers. Alignment and tensioning of the mask occurs 1120 through sensing mask fiducials, and automatically iterating position changes for aligning and tensioning the mask. After successive iterations, a best average mask position is found and alignment is completed after reaching a specified tolerance.

The jig/mask assembly is ready for direction into the coating chamber. The target/coating material source is readied 1125 and brought to full deposition efficiency with shields in place preventing deposition.

The jig/mask assembly is directed 1127 into the coating chamber using an automated mechanism and is transferred to a reciprocating shuttle mechanism. The reciprocating shuttle mechanism moves the jig/mask set toward the mating position and movement of the substrate begins. Both the jig/mask assembly and the substrate reach 1130 mating position and the substrate and mask are mated. The substrate and jig/mask assembly begin 1135 a traverse cycle across the deposition field. Shields are removed from the deposition path allowing deposition 1140 directly through the mask openings onto the substrate. Upon reaching 1145 the end of a deposition field traverse, separation of the substrate and mask occurs 1150 as a result of the mask dropping down. Correction for pattern location offset is applied 1160. The jig/mask set is returned to mating position in synchrony with the next incoming substrate pattern and the deposition cycle is repeated.

The foregoing description of the various embodiments of the invention has been presented for the purposes of illustration and description. It is not intended to be exhaustive or to limit the invention to the precise form disclosed. Many modifications and variations are possible in light of the above teaching. For example, embodiments of the present invention may be implemented in a wide variety of applications. It is intended that the scope of the invention be limited not by this detailed description, but rather by the claims appended hereto.

What is claimed is:

1. An apparatus for depositing a pattern of material on a substrate, comprising:
a delivery roller mechanism from which the substrate is delivered and a receiving roller mechanism upon which the substrate is received;
a deposition source positioned to direct deposition material toward the substrate;
a feed magazine configured to house a plurality of jigs, each of the jigs configured to support a mask having apertures defining a pattern; and
a shuttle mechanism configured to receive the selected jig presented by the feed magazine and establish contact between the mask of the selected jig and the substrate, the shuttle mechanism configured to move the selected jig in line with the substrate and relative to the deposition source so that deposition material passes through the apertures of the mask of the selected jig to develop the pattern of the deposition material on the substrate.

2. The apparatus of claim 1, further comprising an alignment arrangement configured to align the substrate relative to the mask.

3. The apparatus of claim 1, further comprising an alignment arrangement configured to align the mask relative to the substrate.

4. The apparatus of claim 1, further comprising a substrate alignment arrangement configured to adjust a position of the substrate and a mask alignment arrangement configured to adjust a position of the mask of the selected jig, the respective alignment arrangements controllably adjustable to facilitate alignment between the substrate and the mask.

5. The apparatus of claim 1, further comprising a mask alignment mechanism, the mask alignment mechanism configured to adjust a position of the mask relative to the selected jig.

6. The apparatus of claim 5, wherein the mask comprises fiducials and the jig comprises datums, the mask alignment mechanism configured to align the fiducials relative to the datums of the selected jig.

7. The apparatus of claim 5, wherein the mask alignment mechanism is configured to adjust the position of the mask along one axis of the mask relative to the selected jig.

8. The apparatus of claim 5, wherein the mask alignment mechanism is configured to adjust the position of the mask along two orthogonal axes of the mask relative to the selected jig.

9. The apparatus of claim 1, wherein the mask alignment mechanism comprises one or more controllable drivers provided on the selected jig and coupled to the mask, the drivers configured to controllably adjust tensioning of the mask of the selected jig.

10. The apparatus of claim 9, wherein the drivers are configured to controllably adjust tensioning of the mask relative to two orthogonal axes of the mask.

11. The apparatus of claim 1, further comprising a substrate alignment mechanism including markings on the substrate and a web guide that adjusts a transverse position of the substrate to a pre-defined position, wherein the shuttle mechanism is configured to adjust a position of the mask of the selected jig so that a patterned portion of the substrate comes into alignment with the mask when the shuttle mechanism moves the selected jig in line with the substrate.

12. The apparatus of claim 1, further comprising a web location platform arrangement configured to adjust a location of the substrate relative to the mask as the shuttle mechanism moves the selected jig in line with the substrate.

13. The apparatus of claim 12, wherein the web location platform arrangement comprises a support plate and a gas delivery arrangement, the gas delivery arrangement supplying a volume of gas between the substrate and the support plate.

14. The apparatus of claim 13, wherein the web location platform arrangement further comprises at least one roller and the gas delivery arrangement is configured to supply a volume of gas between the substrate and the at least one roller.

15. The apparatus of claim 12, wherein the web location platform arrangement comprises a support plate and a roller disposed adjacent each respective end of the support plate, one or both of the rollers configured to cool the substrate as the substrate moves past the rollers.

16. The apparatus of claim 12, wherein the web location platform arrangement further comprises an oscillator configured produce oscillating motion of the support plate.

17. The apparatus of claim 1, wherein the substrate has a surface defined by a plane, the shuttle mechanism is configured to move the selected jig relative to the substrate in a direction off-plane with respect to the plane of the substrate.

18. The apparatus of claim 17, wherein the shuttle mechanism is configured to move the selected jig in a first off-plane direction so that the mask engages the substrate prior to deposition and to move the selected jig in a second off-plane direction so that the mask disengages with the substrate after completion of the deposition.

19. The apparatus of claim 1, wherein the shuttle mechanism is configured to move the selected jig in a reciprocating manner for repeated use of the selected jig during deposition.

20. The apparatus of claim 1, further comprising an outfeed mechanism and an outfeed magazine configured to house a plurality of used jigs, the outfeed mechanism moving the used jigs from the shuttle mechanism to the outfeed magazine.

21. The apparatus of claim 1, wherein the feed mechanism is configured to receive used jigs presented by the shuttle mechanism.

22. The apparatus of claim 1, wherein the masks of at least some of the plurality of jigs define patterns differing from the masks of others of the plurality of jigs.

23. The apparatus of claim 1, wherein the substrate comprises a continuous web.

24. The apparatus of claim 1, wherein the mask comprises a polymeric film.

25. A method of depositing a pattern of material on a substrate, comprising:
moving a selected jig of a plurality of jigs from a feed magazine, each of the jigs configured to support a mask having apertures defining a pattern;
moving a substrate relative to a deposition source;
transporting the selected jig into engagement with the substrate at a first location;
passing, with the selected jig engaging the substrate and moving in synchrony with the substrate, deposition material through the apertures of the mask of the selected jig to develop the pattern of the deposition material on the substrate;
disengaging the selected jig relative to the substrate at the second location; and
returning the selected jig to the feed magazine or other facility after use of the selected jig.

26. The method of claim 25, comprising returning the selected jig to a mating position after the synchronous movement of the selected jig and the substrate.

27. The method of claim 25, comprising cooling at least the substrate and mask of the selected jig during development of the pattern of the deposition material on the substrate.

28. The method of claim 25, further comprising aligning the substrate relative to the mask.

29. The method of claim 25, further comprising aligning the mask relative to the substrate.

30. The method of claim 25, further comprising adjusting a position of the substrate and a position of the mask of the selected jig to provide alignment between the substrate relative to the mask.

31. The method of claim 25, comprising adjusting the position of the mask along one axis of the mask relative to the selected jig.

32. The method of claim 25, comprising adjusting the position of the mask along two orthogonal axes of the mask relative to the selected jig.

33. The method of claim 25, comprising automatically adjusting tensioning of the mask of the selected jig relative to one axis of the mask.

34. The method of claim 25, comprising automatically adjusting tensioning of the mask of the selected jig relative to two orthogonal axes of the mask.

35. The method of claim 25, wherein the masks of at least some of the plurality of jigs define patterns differing from the masks of others of the plurality of jigs.

36. The method of claim 25, further comprising:
determining alignment offset of a deposition cycle; and
adjusting alignment between the mask of the selected jig or other jig and the substrate prior to a subsequent deposition cycle.

37. An apparatus for depositing a pattern of material on a substrate, comprising:
means for moving a selected jig of a plurality of jigs from a feed magazine, each of the jigs configured to support a mask having apertures defining a pattern;
means for moving a substrate relative to a deposition source;
means for transporting the selected jig into engagement with the substrate at a first location;
means for passing deposition material through the apertures of the mask of the selected jig to develop the pattern of the deposition material on the substrate;
means for disengaging the selected jig relative to the substrate at the second location; and
means for returning the selected jig to the feed magazine or other facility after use of the selected jig.
